(19) United States
(12) Patent Application Publication
(10) Pub. No.: US 2024/0429122 A1
(43) Pub. Date: Dec. 26, 2024

(54) THERMALLY CONDUCTIVE INTERPOSER, A DEVICE IMPLEMENTING A THERMALLY CONDUCTIVE INTERPOSER, AND PROCESSES FOR IMPLEMENTING THE SAME

(71) Applicant: WOLFSPEED, INC., Durham, NC (US)

(72) Inventors: Kyle BOTHE, Cary, NC (US); James TWEEDIE, Durham, NC (US); Fabian RADULESCU, Chapel Hill, NC (US); Michael SCHUETTE, Sunbury, OH (US); Jeremy FISHER, Raleigh, NC (US); Basim NOORI, Durham, NC (US); Scott SHEPPARD, Durham, NC (US)

(21) Appl. No.: 18/340,607

(22) Filed: Jun. 23, 2023

(51) Int. Cl. H01L 23/373; H01L 21/48; H01L 23/00; H01L 23/498

(52) U.S. Cl. CPC H01L 23/373; H01L 21/4857; H01L 23/49822; H01L 24/08; H01L 2224/08225

(57) ABSTRACT

A thermally conductive interposer includes an interposer substrate having a first substrate surface and a second substrate surface. The first substrate surface being configured to be attached to a first device component. The second substrate surface being configured to be attached to a second device component. The interposer substrate being configured to support the second device component on the first device component and integrate the first device component and the second device component within a microelectronic device. Further, the interposer substrate is configured to transfer heat between the first device component and the second device component; and the interposer substrate is configured to be electrically nonconductive.

### FIELD OF THE DISCLOSURE

The disclosure relates to a thermally conductive interposer. The disclosure further relates to a device implementing a thermally conductive interposer. Additionally, the disclosure relates to processes for implementing a thermally conductive interposer. Further, the disclosure relates to processes for implementing a device implementing a thermally conductive interposer.

### BACKGROUND OF THE DISCLOSURE

Current microelectronics typically use interposers and/or printed circuit boards (PCBs) for heterogeneous integration requiring fast electrical connection. These interposers and/or PCBs have inefficiencies resulting from the intrinsic properties of their constituent material, which most commonly is glass, silicon (Si), and/or fiberglass impregnated with epoxy. Accordingly, the interposers have poor thermal conductivity.

Additionally, the mechanical integrity of the interposer is also material dependent, which can pose manufacturing challenges. For example, silicon-based interposers require complex stress reduction to mitigate reliability issues.

Accordingly, what is needed is an interposer configured with improved thermal conductivity and/or improved mechanical integrity.

### SUMMARY OF THE DISCLOSURE

In one aspect, a thermally conductive interposer includes an interposer substrate having a first substrate surface and a second substrate surface. The thermally conductive interposer in addition includes the first substrate surface being configured to be attached to a first device component. The interposer moreover includes the second substrate surface being configured to be attached to a second device component. The interposer also includes the interposer substrate being configured to support the second device component on the first device component and integrate the first device component and the second device component within a microelectronic device. The interposer further includes where the interposer substrate include a material having a Youngs Modulus greater than 200 GPa (Giga Pascals). The interposer in addition includes where the interposer substrate is configured to transfer heat between the first device component and the second device component. The interposer moreover includes where the interposer substrate is configured to be electrically nonconductive.

In one aspect, a process includes configuring an interposer substrate to include a first substrate surface and a second substrate surface. The process in addition includes configuring the first substrate surface to be attached to a first device component. The process moreover includes configuring the second substrate surface to be attached to a second device component. The process also includes configuring the interposer substrate to support the second device component on the first device component and integrate the first device component and the second device component within a microelectronic device. The process further includes where the interposer substrate include a material having a Youngs Modulus greater than 200 GPa (Giga Pascals). The process in addition includes where the interposer substrate is configured to transfer heat between the first device component and the second device component. The process moreover includes where the interposer substrate is configured to be electrically nonconductive.

In one aspect, a thermally conductive interposer includes an interposer substrate having a first substrate surface and a second substrate surface. The thermally conductive interposer in addition includes the first substrate surface being configured to be attached to a first device component. The interposer moreover includes the second substrate surface being configured to be attached to a second device component. The interposer also includes the interposer substrate being configured to support the second device component on the first device component and integrate the first device component and the second device component within a microelectronic device. The interposer further includes where the interposer substrate include a material having a thermal conductivity greater than 2 W/cm-K (watts per centimeter Kelvin). The interposer in addition includes where the interposer substrate is configured to transfer heat between the first device component and the second device component. The interposer moreover includes where the interposer substrate is configured to be electrically nonconductive.

In one aspect, a process includes configuring an interposer substrate to include a first substrate surface and a second substrate surface. The process in addition includes configuring the first substrate surface to be attached to a first device component. The process moreover includes configuring the second substrate surface to be attached to a second device component. The process also includes configuring the interposer substrate to support the second device component on the first device component and integrate the first device component and the second device component within a microelectronic device. The process further includes where the interposer substrate include a material having a thermal conductivity greater than 2 W/cm-K (watts per centimeter Kelvin). The process in addition includes where the interposer substrate is configured to transfer heat between the first device component and the second device component. The process moreover includes where the interposer substrate is configured to be electrically nonconductive.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 illustrates a cross-sectional side view of a thermally conductive interposer according to the disclosure.

FIG. 2 illustrates a perspective view of the thermally conductive interposer according to FIG. 1.

FIG. 3 illustrates a front view of the thermally conductive interposer according to FIG. 1.

FIG. 4 illustrates a front view of a microelectronic device implementing the thermally conductive interposer according to FIG. 1.

FIG. 5 illustrates a cross-sectional side view of a thermally conductive interposer according to the disclosure.

FIG. 6 illustrates a perspective view of the thermally conductive interposer according to FIG. 5.

FIG. 7 illustrates a front view of the thermally conductive interposer according to FIG. 5.

FIG. 8 illustrates a cross-sectional side view of a thermally conductive interposer according to the disclosure.

FIG. 9 illustrates a perspective view of the thermally conductive interposer according to FIG. 8.

FIG. 10 illustrates a front view of the thermally conductive interposer according to FIG. 5.

FIG. 11 illustrates a microelectronic device implementing the thermally conductive interposer according to FIG. 8.

FIG. 12 illustrates a process of implementing the thermally conductive interposer according to aspects of the disclosure.

The disclosed interposer provides a method to transfer heat from components through the substrate material. Standard designs use silicon, glass, or other insulators. These materials are poor thermal conductors. This causes poor heat transfer from the components to the package.

The disclosed interposer uses an electrically insulating material that is thermally conductive. This ensures configurations, such as front and backside redistribution lines (RDL), are isolated while also providing a thermal path for heat to the package. In aspects, the disclosed interposer includes a material having a thermal conductivity greater than 2 W/cm-K (watts per centimeter Kelvin).

In aspects, the disclosed interposer may include front and/or backside redistribution lines. In aspects, the redistribution lines may include one or a combination of the following: metal traces, metal bond pads, passive components, such as capacitors, inductors, resistors, and/or the like, copper (cu) pillars, solder bumps, a dielectric portion, such as a polyimide/spin on dielectric, and/or the like.

In aspects, the disclosed interposer may be very useful for any microelectronic component that requires a thermally conductive interposer for heterogeneously integrated components.

In further aspects, given a complexity and cost to create silicon carbide (SiC) having a resistivity greater than 1e5 ohm-cm (ohm centimeter), it may not be feasible to use such a material for low cost applications that require an interposer. In aspects, the disclosed interposer may be implemented using lower resistivity substrates, which are less costly. In this regard, lower resistivity substrates can maintain a high blocking voltage while still achieving high thermal conductivity characteristics. More specifically, by using a SiC material with moderate resistivity, such as material having a resistivity of approximately 1000 ohm-cm, the disclosed interposer may be manufactured that is cost effective and utilizes improved material advantages that SiC materials have over materials, such as Si, glass, and/or the like.

In this regard, the disclosed interposer utilizes SiC, which has a number of advantages including: a bandgap greater than 2 eV (electron volt), a breakdown strength greater than 1 MV/cm (Mega volts per centimeter), a melting point greater than 1500 degrees C. (Celsius), dielectric constant less than 11, a Youngs Modulus greater than 200 GPa (Giga Pascals), a thermal conductivity greater than 2 W/cm-K, and/or the like.

More specifically, implementation of the disclosed interposer with a material having band gap above 2 eV may ensure that in environments below 300 degrees C., the interposer will be non-conductive. This value is the intrinsic temperature range. This value should be above 300 degrees C.

Further, implementation of the disclosed interposer with a material having breakdown strength greater than 1 MV/cm, may ensure the interposer can withstand high electric fields.

Additionally, implementation of the disclosed interposer with a material having melting point greater than 1500 degrees C., may enable integration with many microelectronic fabrication techniques by reducing the effect of diffusion and thermal budget.

Further, implementation of the disclosed interposer with a material having a dielectric constant less than 11, may allow reduction of the thickness of the interposer without increasing parasitic capacitances

Additionally, implementation of the disclosed interposer with a material having a Youngs Modulus greater than 200 GPa may mitigate stress and/or strain and improve the thermal robustness of the interposer with the components.

Moreover, implementation of the disclosed interposer with a material having a thermal conductivity greater than 2 W/cm-K may improve thermal management for designs and implementations in microelectronics. For example, certain SiC materials have a Youngs modulus of about 450 GPa, in comparison to certain Si materials having a Youngs modulus 170-185 GPa. In this regard, it is noted that SiC has a higher Youngs modulus. A Youngs modulus indicates that for a given elastic strain for the disclosed interposer, the stress and/or the strain is lower for SiC in comparison to that of Si. This reduction in stress and/or the strain will reduce that amount of stress and/or the strain transferred to the microelectronic components.

The disclosed interposer may implement a number of materials including: a bulk SiC substrate, a bulk Diamond substrate, a bulk GaN (Gallium nitride) substrate, a bulk AlN (Aluminum nitride) substrate, a bulk sapphire substrate, and/or the like. Further, the disclosed interposer may implement a number of material combinations including: GaN on SiC, GaN on Diamond, Diamond on SiC, SiC on Diamond, and/or the like. Further, the disclosed interposer may implement a layer on top of one of the substrate materials such as GaN on SiC.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects, as the skilled artisan would recognize, even if not explicitly stated herein. Descriptions of well-known components and processing techniques may be omitted so as not to unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings and in the different embodiments disclosed.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

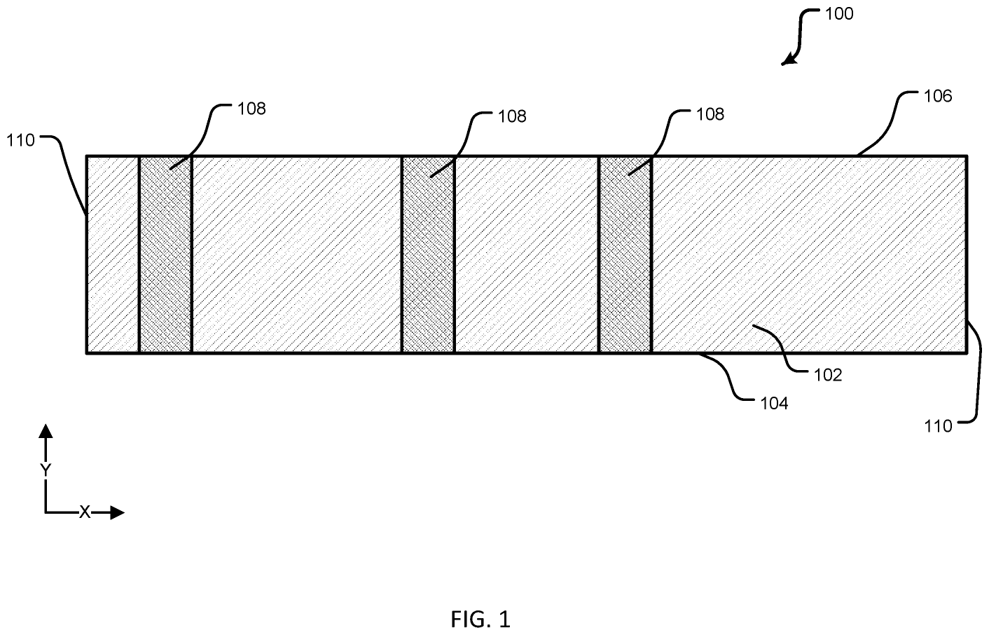

FIG. 1 illustrates a cross-sectional side view of a thermally conductive interposer according to the disclosure.

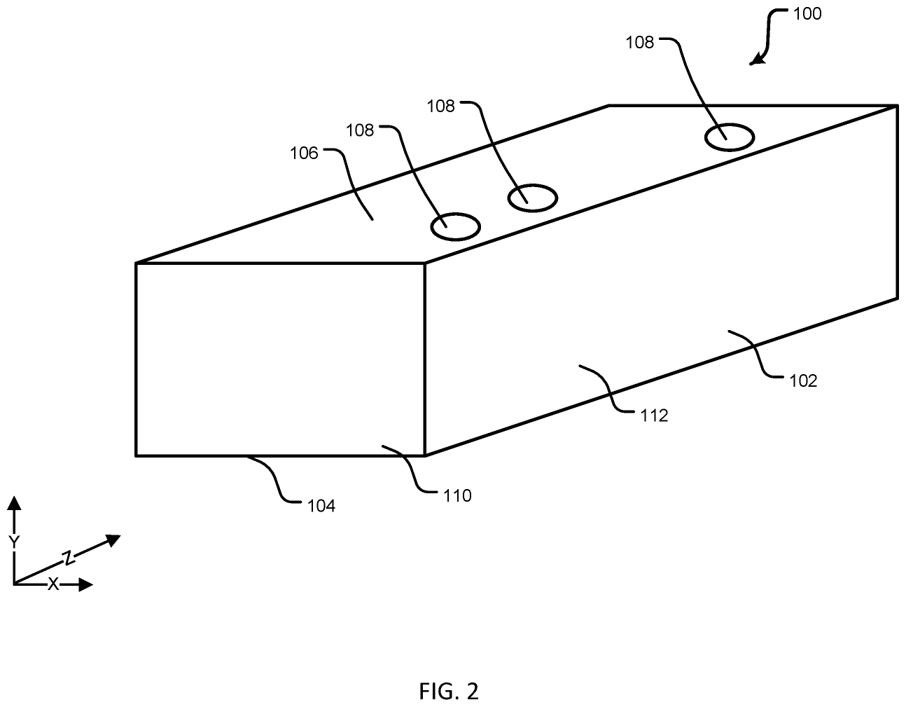

FIG. 2 illustrates a perspective view of the thermally conductive interposer according to FIG. 1.

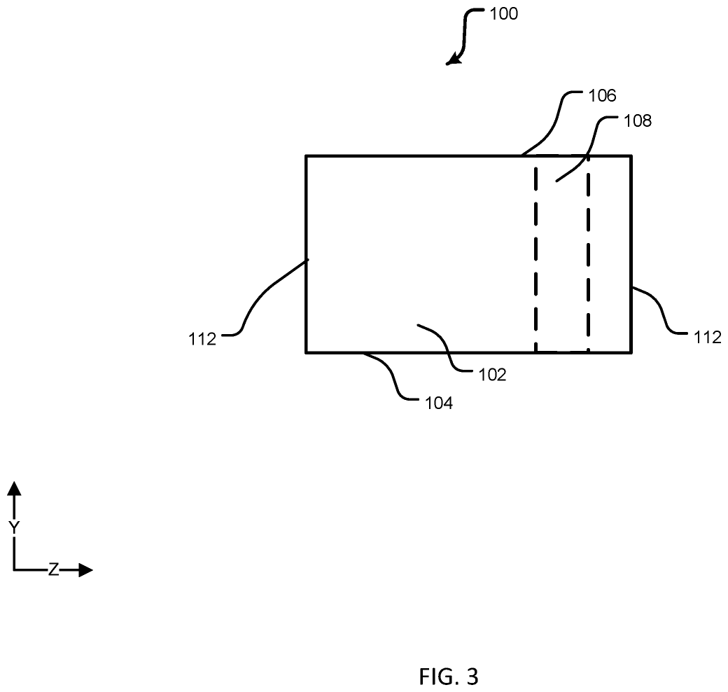

FIG. 3 illustrates a front view of the thermally conductive interposer according to FIG. 1.

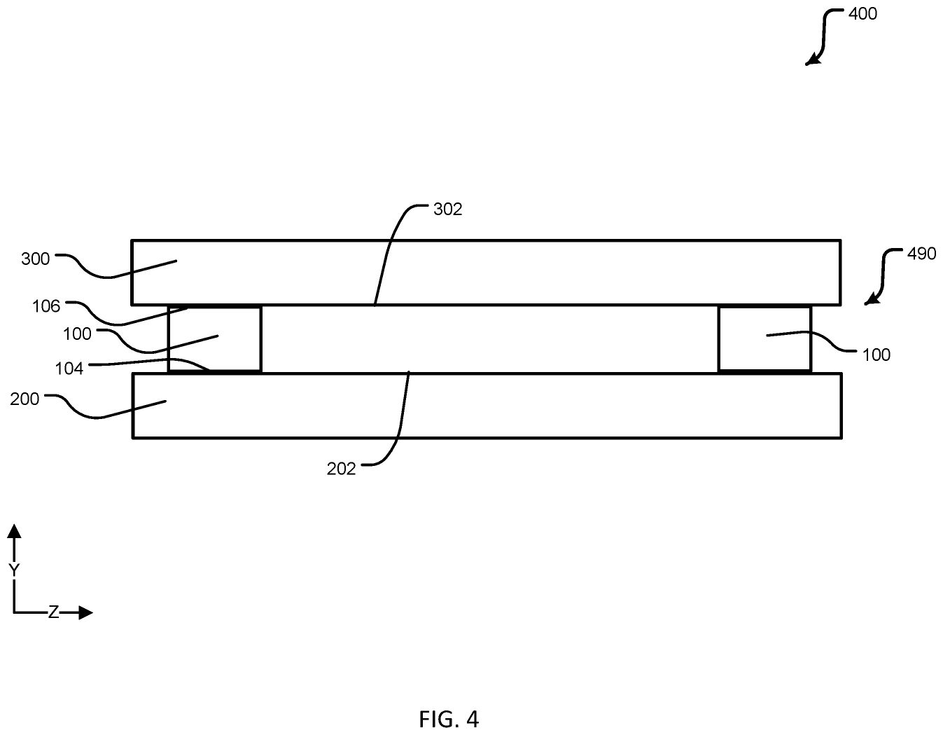

FIG. 4 illustrates a front view of a microelectronic device implementing the thermally conductive interposer according to FIG. 1.

In particular, FIG. 1 illustrates a cross-sectional side view of a thermally conductive interposer 100 according to the disclosure. The thermally conductive interposer 100 may include an interposer substrate 102 having a first substrate surface 104 and a second substrate surface 106.

Additionally, the thermally conductive interposer 100 may include a filled interconnect 108. The filled interconnect 108 may extend through the interposer substrate 102 from the first substrate surface 104 to the second substrate surface 106. In this regard, the filled interconnect 108 may be configured to transfer heat between first substrate surface 104 and the second substrate surface 106.

With reference to FIG. 4, the first substrate surface 104 may be configured to be attached to a first device component 200. Moreover, the second substrate surface 106 may be configured to be attached to a second device component 300. Additionally, the interposer substrate 102 may be configured to support the second device component 300 on the first device component 200 and integrate the first device component 200 and the second device component 300 within a microelectronic device 400. In aspects, the thermally conductive interposer 100 may be attached to the first device component 200 and/or the second device component 300 by an adhesive, soldering, sintering, eutectic bonding, ultrasonically welding, and/or the like.

In aspects, there may be any number of implementations of the thermally conductive interposer 100 within the microelectronic device 400. Further, the thermally conductive interposer 100 may be implemented with additional components of the microelectronic device 400 (not shown).

In aspects, the thermally conductive interposer 100 may be a structure to provide integration between the first device component 200 and the second device component 300. In particular, the thermally conductive interposer 100, the first device component 200, the second device component 300, and/or the like may form a component stack 490 within the microelectronic device 400. In aspects, the thermally conductive interposer 100 may be configured within the microelectronic device 400 as a configuration to stack various components of the microelectronic device 400, such as the first device component 200 and the second device component 300. In aspects, the thermally conductive interposer 100 may be configured to facilitate vertical interconnection of components of the microelectronic device 400, such as the first device component 200 and the second device component 300. As further described herein, the thermally conductive interposer 100 may provide additional functionality including implementing power and/or signal connections between components of the microelectronic device 400, such as the first device component 200 and the second device component 300.

In particular, the thermally conductive interposer 100 provides a method to transfer heat from components, such as the first device component 200 and/or the second device component 300 through a material of the interposer substrate 102 and/or through the filled interconnect 108. In particular, the thermally conductive interposer 100 and/or the interposer substrate 102 uses an electrically insulating material that is thermally conductive. This ensures components of the microelectronic device 400, such as the first device component 200 and/or the second device component 300, as well as configurations on and/or in the thermally conductive interposer 100 may be electrically isolated while also providing a thermal path for transferring heat within the microelectronic device 400.

In aspects, the thermally conductive interposer 100 and/or the interposer substrate 102 includes a material having a thermal conductivity greater than 2 W/cm-K. Moreover, in aspects the thermally conductive interposer 100 and/or the interposer substrate 102 includes a material having a thermal conductivity greater than 1.50 W/cm-K, 2.00 W/cm-K, 10.0 W/cm-K, or 20.0 W/cm-K. Further, in aspects the thermally conductive interposer 100 and/or the interposer substrate 102 includes a material having a thermal conductivity of 1.50 W/cm-K-25.0 W/cm-K, 1.50 W/cm-K-2.00 W/cm-K, or 2.00 W/cm-K-10.0 W/cm-K, 10.0 W/cm-K-20.0 W/cm-K, or 20.0 W/cm-K-25.0 W/cm-K.

In further aspects, given a complexity and cost to create silicon carbide (SiC) having a resistivity greater than 100,000 ohm-cm (ohm centimeter), it may not be feasible to use such a material for low cost applications that require an interposer. In aspects, the thermally conductive interposer 100 and/or the interposer substrate 102 may be implemented using lower resistivity substrates, which are less costly. In this regard, implementations of the thermally conductive interposer 100 and/or the interposer substrate 102 having lower resistivity substrates can maintain a high blocking voltage while still achieving high thermal conductivity characteristics.

More specifically, by implementing the thermally conductive interposer 100 and/or the interposer substrate 102 using a SiC material with moderate resistivity, such as material having a resistivity of approximately 1000 ohm-cm, implementations of the thermally conductive interposer 100 may be manufactured that is cost effective and utilizes improved material advantages that SiC materials have over materials, such as Si, glass, and/or the like.

In aspects, the thermally conductive interposer 100 and/or the interposer substrate 102 may be implemented using a SiC material having a resistivity less than 100,000 ohm-cm, 50,000 ohm-cm, 10,000 ohm-cm, 5,000 ohm-cm, or 2,000 ohm-cm. In aspects, the thermally conductive interposer 100 and/or the interposer substrate 102 may be implemented using a SiC material having a resistivity of 100,000 ohm-cm-50,000 ohm-cm, 50,000 ohm-cm-10,000 ohm-cm, 10,000 ohm-cm-5,000 ohm-cm, 5,000 ohm-cm-, 000 ohm-cm, or 2,000 ohm-cm-800 ohm-cm.

In this regard, the thermally conductive interposer 100 and/or the interposer substrate 102 may utilize SiC, which has a number of advantages including: a bandgap greater than 2 eV (electron volt), a breakdown strength greater than 1 MV/cm (Mega volts per centimeter), a melting point greater than 1500 degrees C. (Celsius), dielectric constant less than 11, a Youngs Modulus greater than 200 GPa (Giga Pascals), a thermal conductivity greater than 2 W/cm-K, and/or the like.

More specifically, implementation of the thermally conductive interposer 100 and/or the interposer substrate 102 with a material having band gap above 2 eV may ensure that in environments below 300 degrees C., the interposer will be non-conductive. This value is the intrinsic temperature range.

Further, implementation of the thermally conductive interposer 100 and/or the interposer substrate 102 with a material having breakdown strength greater than 1 MV/cm, may ensure the thermally conductive interposer 100 can withstand high electric fields.

Additionally, implementation of the thermally conductive interposer 100 and/or the interposer substrate 102 with a material having melting point greater than 1500 degrees C., may enable integration with many microelectronic fabrication techniques by reducing the effect of diffusion and thermal budget.

Further, implementation of the thermally conductive interposer 100 and/or the interposer substrate 102 with a material having a dielectric constant less than 11, may allow reduction of the thickness of the interposer without increasing parasitic capacitances

Additionally, implementation of the thermally conductive interposer 100 and/or the interposer substrate 102 with a material having a Youngs modulus: greater than 200 GPa may mitigate stress and improve the thermal robustness of the interposer with the components. Further, the thermally conductive interposer 100 and/or the interposer substrate 102 may be implemented with a material having a Youngs modulus greater than 200 GPa, 300 GPa, 400 GPa, or 500 GPa. Additionally, the thermally conductive interposer 100 and/or the interposer substrate 102 may be implemented with a material having a Youngs modulus range of 200 GPa-300 GPa, 300 GPa-400 GPa, or 400 GPa-500 GPa.

Moreover, implementation of the thermally conductive interposer 100 and/or the interposer substrate 102 with a material having a thermal conductivity greater than 2 W/cm-K may improve thermal management for designs and implementations in microelectronics.

For example, certain SiC materials have a Youngs modulus of about 450 GPa, in comparison to certain Si materials having a Youngs modulus 170-185 GPa. In this regard, it is noted that SiC has a higher Youngs modulus. A Youngs modulus indicates that for a given elastic strain for the disclosed interposer, the stress and/or the strain is lower for SiC in comparison to that of Si. This reduction in stress and/or the strain will reduce that amount of stress and/or the strain transferred to the microelectronic components.

The interposer substrate 102 may include silicon carbide (SiC), may be made of Silicon Carbide (SiC), and/or the like. In some aspects, the interposer substrate 102 may be a semi-insulating SiC substrate, a p-type substrate, an n-type substrate, and/or the like. In some aspects, the interposer substrate 102 may be very lightly doped. In one aspect, the interposer substrate 102 may be formed of SiC selected from the group of 6H, 4H, 15R, 3C SiC, or the like. In one aspect, the interposer substrate 102 may be formed of SiC that may be semi-insulating and doped with vanadium or any other suitable dopant or undoped of high purity with defects providing the semi-insulating properties.

The thermally conductive interposer 100 and/or the interposer substrate 102 may implement a number of materials including: a bulk SiC substrate, a Bulk Diamond substrate, a bulk GaN (Gallium nitride) substrate, a bulk AlN (Aluminum nitride) substrate, a bulk sapphire substrate, and/or the like. Further, the thermally conductive interposer 100 may implement a number of material combinations including: GaN on SiC, GaN on Diamond, Diamond on SiC, SiC on Diamond, and/or the like. Further, the thermally conductive interposer 100 may implement a layer on top of one of the materials of the interposer substrate 102 such as GaN on SiC.

With further reference to FIG. 2, the interposer substrate 102 may include end surfaces 110 extending from the first substrate surface 104 to the second substrate surface 106. In aspects, the end surfaces 110 may be arranged in a vertical plane. In aspects, the end surfaces 110 may be arranged in the Y-X plane as illustrated in FIG. 2.

Further, the interposer substrate 102 may include side surfaces 112 extending from the first substrate surface 104 to the second substrate surface 106. In aspects, the side surfaces 112 may be arranged in a vertical plane. In aspects, the side surfaces 112 may be arranged in the Y-Z plane as illustrated in FIG. 2.

Moreover, the end surfaces 110 of the interposer substrate 102 may extend laterally between implementations of the side surfaces 112 of the interposer substrate 102. Further, the side surfaces 112 of the interposer substrate 102 may extend longitudinally between implementations of the end surfaces 110 of the interposer substrate 102.

It should be noted that the relative dimensions of the thermally conductive interposer 100, the first device component 200, and/or the second device component 300 illustrated in FIG. 4 are not necessarily to scale. However, in particular aspects, a surface area of the second substrate surface 106 and/or a surface area of the first substrate surface 104 will be smaller than a surface area of a surface 302 of the second device component 300 and/or a surface area of a surface 202 of the first device component 200.

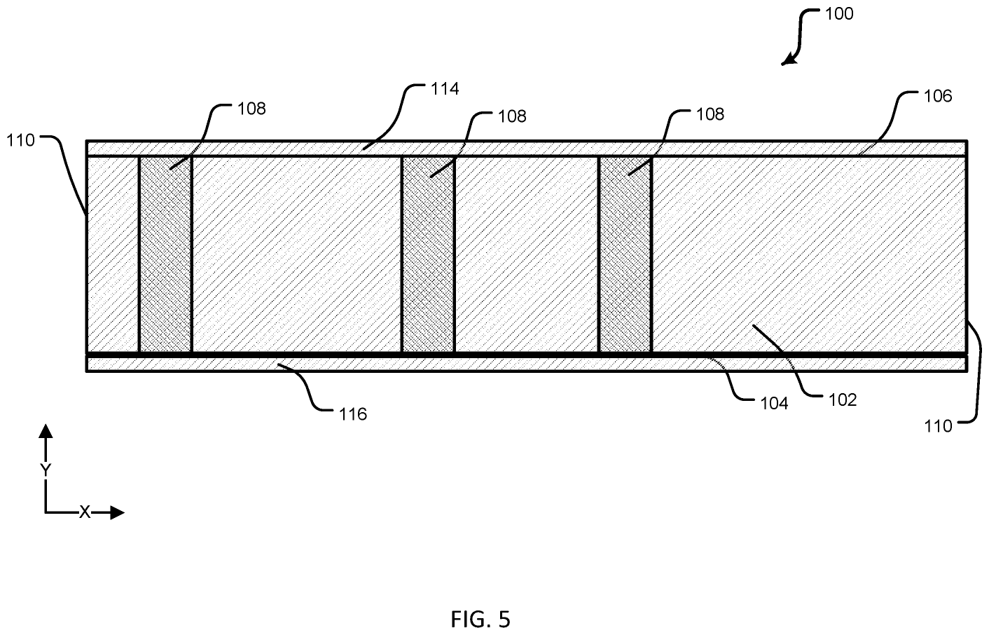

FIG. 5 illustrates a cross-sectional side view of a thermally conductive interposer according to the disclosure.

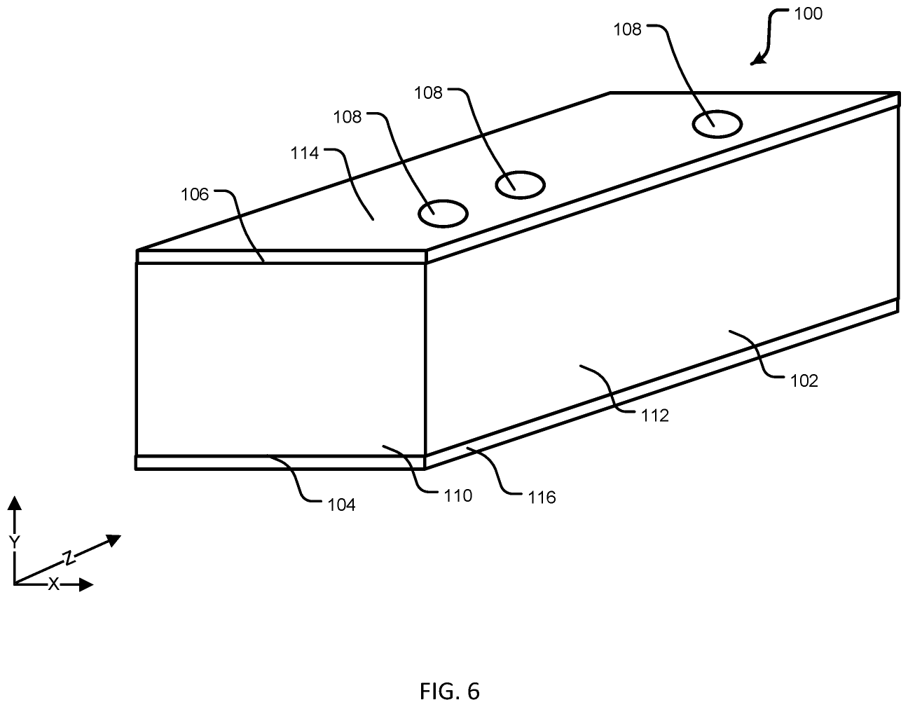

FIG. 6 illustrates a perspective view of the thermally conductive interposer according to FIG. 5.

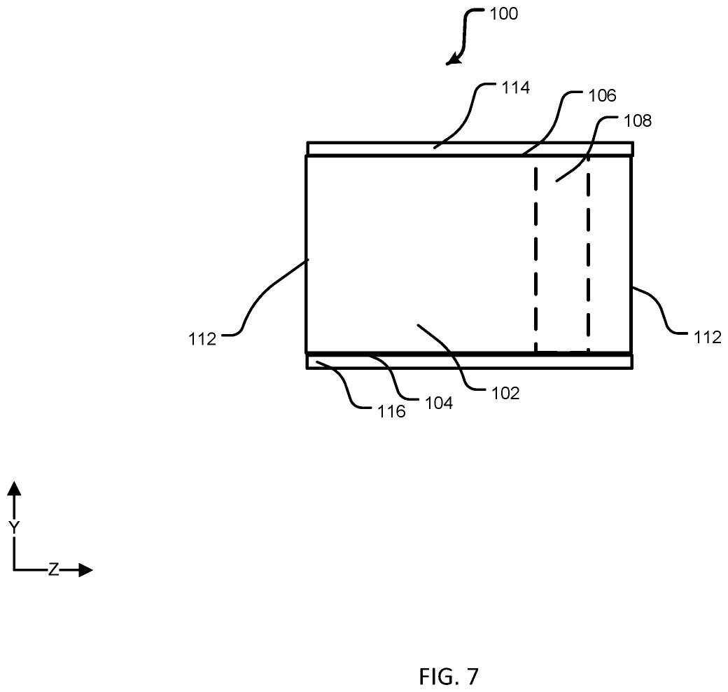

FIG. 7 illustrates a front view of the thermally conductive interposer according to FIG. 5.

In particular, FIG. 5, FIG. 6, and FIG. 7 illustrate further implementations of the thermally conductive interposer 100. In this regard, the thermally conductive interposer 100 illustrated in FIG. 5, FIG. 6, and FIG. 7 may optionally include any of the other aspects of the thermally conductive interposer 100 described herein. Further, other aspects of the thermally conductive interposer 100 described herein may optionally include the features illustrated in FIG. 5, FIG. 6, and FIG. 7.

In particular aspects, the thermally conductive interposer 100 may further include a material layer 114 arranged on the second substrate surface 106 of the interposer substrate 102. In particular aspects, the thermally conductive interposer 100 may further include the material layer 114 arranged directly on the first substrate surface 104 of the interposer substrate 102.

In particular aspects, the thermally conductive interposer 100 may further include a material layer 116 arranged on the second substrate surface 106 of the interposer substrate 102. In particular aspects, the thermally conductive interposer 100 may further include the material layer 116 arranged directly on the second substrate surface 106 of the interposer substrate 102.

In aspects, the material layer 114 may be a GaN layer, a SiC layer, and/or the like. In aspects, the material layer 114 may be a GaN layer on a SiC material implementation of the interposer substrate 102, the material layer 114 may be a GaN layer on a Diamond material implementation of the interposer substrate 102, the material layer 114 may be a Diamond layer on a SiC material implementation of the interposer substrate 102, the material layer 114 may be SiC layer on a Diamond material implementation of the interposer substrate 102, and/or the like.

In aspects, the material layer 116 may be a GaN layer, a SiC layer, and/or the like. In aspects, the material layer 114 may be a GaN layer on a SiC material implementation of the interposer substrate 102, the material layer 116 may be a GaN layer on a Diamond material implementation of the interposer substrate 102, the material layer 116 may be a Diamond layer on a SiC material implementation of the interposer substrate 102, the material layer 116 may be SiC layer on a Diamond material implementation of the interposer substrate 102, and/or the like.

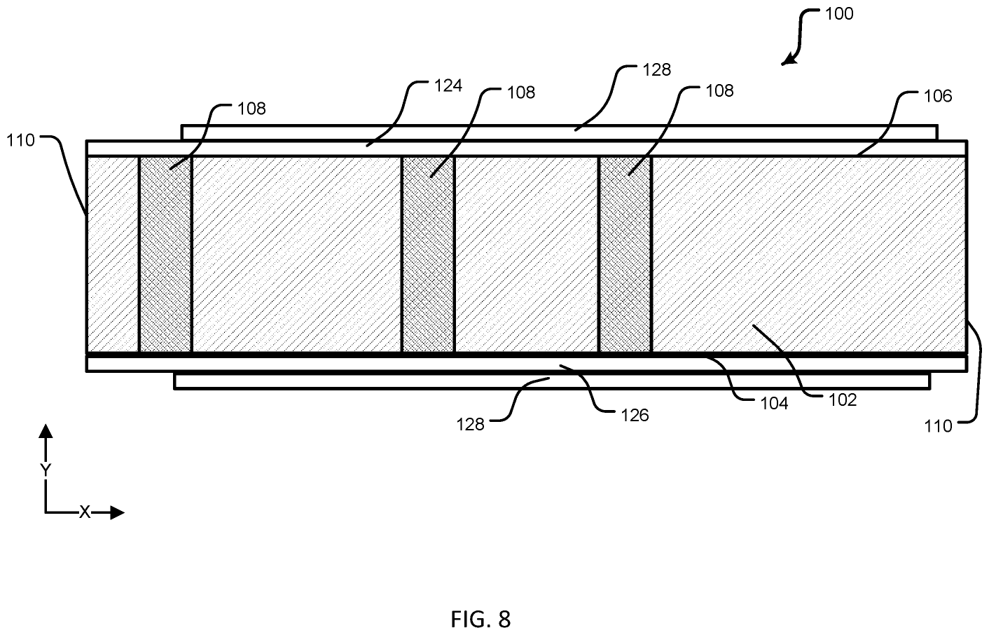

FIG. 8 illustrates a cross-sectional side view of a thermally conductive interposer according to the disclosure.

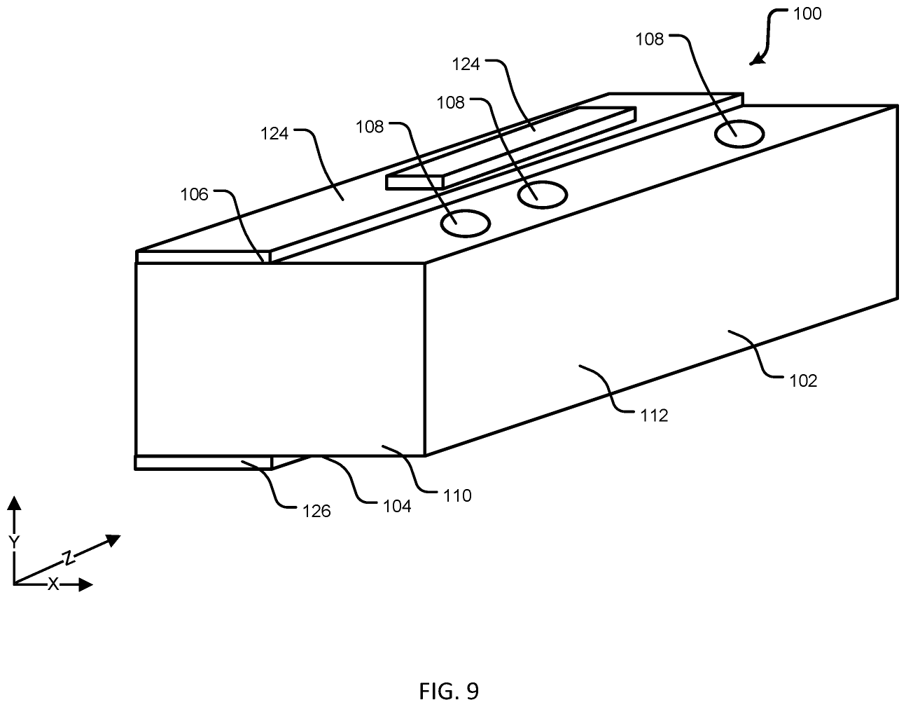

FIG. 9 illustrates a perspective view of the thermally conductive interposer according to FIG. 8.

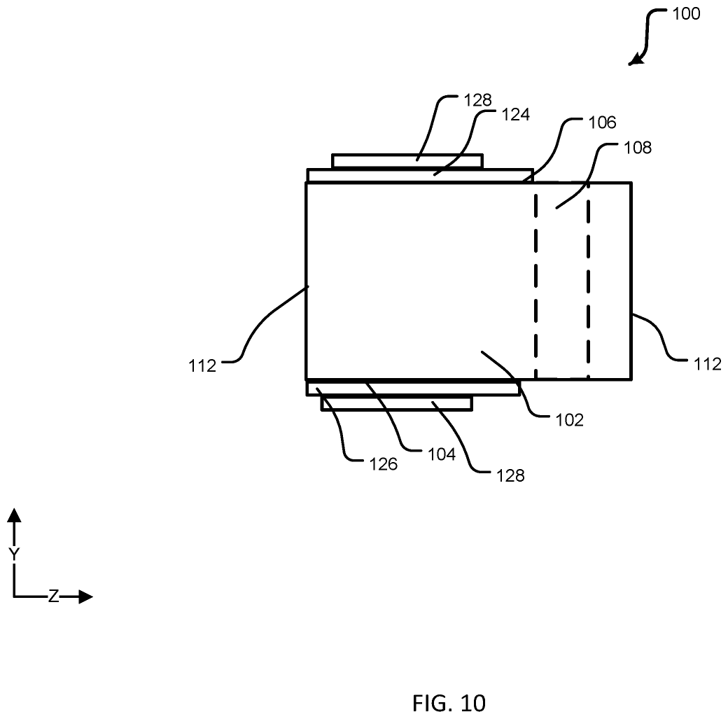

FIG. 10 illustrates a front view of the thermally conductive interposer according to FIG. 5.

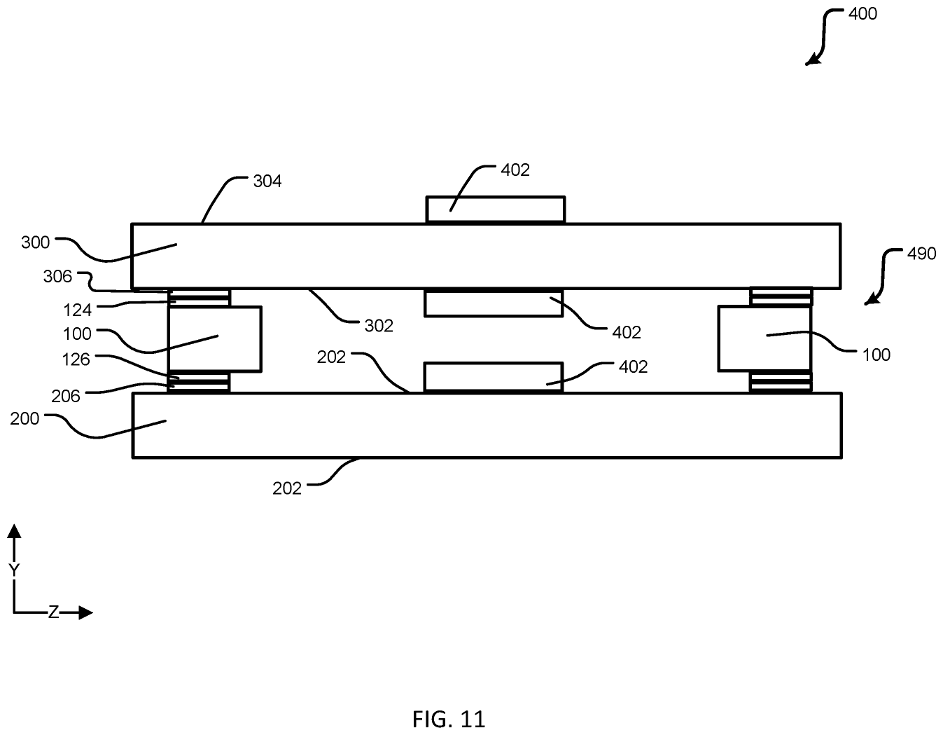

FIG. 11 illustrates a microelectronic device implementing the thermally conductive interposer according to FIG. 8.

In particular, FIG. 8, FIG. 9, FIG. 10, and FIG. 11 illustrate further implementations of the thermally conductive interposer 100. In this regard, the thermally conductive interposer 100 illustrated in FIG. 8, FIG. 9, FIG. 10, and FIG. 11 may optionally include any of the other aspects of the thermally conductive interposer 100 described herein. Further, other aspects of the thermally conductive interposer 100 described herein may optionally include the features illustrated in FIG. 8, FIG. 9, FIG. 10, and FIG. 11.

As illustrated in FIG. 8, the thermally conductive interposer 100 may further include a component configuration 124 arranged on the second substrate surface 106 of the interposer substrate 102. Additionally or alternatively, the thermally conductive interposer 100 may further include a component configuration 126 arranged on the first substrate surface 104 of the interposer substrate 102.

In aspects, the component configuration 124 and/or the component configuration 126 may be redistribution lines, circuit components, a metallic surface, and/or the like. As illustrated in FIG. 9, the component configuration 124 and/or the component configuration 126 may be arranged in area of the second substrate surface 106 spaced from the filled interconnect 108. Accordingly, the component configuration 124 and/or the component configuration 126 may be electrically isolated from the filled interconnect 108.

In aspects, the component configuration 124 and/or the component configuration 126 may include one or more layers of metal, one or more layers of dielectric material, and/or the like. In aspects, the component configuration 124 and/or the component configuration 126 may include front and/or backside redistribution lines. In aspects, the redistribution lines may include one or a combination of the following: metal traces, metal bond pads, passive components 128, such as capacitors, inductors, resistors, and/or the like, copper (cu) pillars, solder bumps, a dielectric portion, such as a polyimide/spin on dielectric, and/or the like.

In aspects, the component configuration 124 and/or the component configuration 126 may implement the passive components 128, such as a capacitor, an inductor, a spiral inductor, a transmission line, a resistor, a combination thereof, and/or the like.

In aspects, the component configuration 124 and/or the component configuration 126 may include one or more metallizations, dielectric materials, patterned metal layers, and/or the like to implement passive components 128, such as a capacitor, an inductor, a spiral inductor, a transmission line, a resistor, combinations thereof, and/or the like.

In aspects, the component configuration 124 and/or the component configuration 126 may implement a resistor that may be defined by the width, length, and/or height of a metal portion implemented as part of the component configuration 124 and/or the component configuration 126. The resistor may additionally or alternatively be implemented as a thin film resistor, a thick film resistor, a printed thin film resistor, a printed thick film resistor, and/or the like.

In aspects, the component configuration 124 and/or the component configuration 126 may implement an inductor that may be defined by the width, length, and/or height of a metal portion implemented as part of the component configuration 124 and/or the component configuration 126. The inductor may be implemented as a spiral. A spiral construction of the inductor may be formed from a metal.

In aspects, the component configuration 124 and/or the component configuration 126 may implement a capacitor that may include a capacitor top plate, a capacitor bottom plate, and a dielectric layer arranged therebetween. In aspects, the component configuration 124 and/or the component configuration 126 may form a surface for attachment to a surface mount device (SMD).

In aspects, the component configuration 126 of the thermally conductive interposer 100 may be attached to the first device component 200 by an adhesive, soldering, sintering, eutectic bonding, ultrasonically welding, and/or the like. In aspects, the component configuration 124 of the thermally conductive interposer 100 may be attached to the second device component 300 by an adhesive, soldering, sintering, eutectic bonding, ultrasonically welding, and/or the like.

With reference to FIG. 11, the second device component 300 may further include a bond pad 306. The bond pad 306 may be arranged on the surface 302. In aspects, the component configuration 124 of the thermally conductive interposer 100 may be attached to the bond pad 306 of the second device component 300 by an adhesive, soldering, sintering, eutectic bonding, ultrasonically welding, and/or the like.

With further reference to FIG. 11, the first device component 200 may further include a bond pad 206. The bond pad 206 may be arranged on the surface 202. In aspects, the component configuration 126 of the thermally conductive interposer 100 may be attached to the bond pad 206 of the first device component 200 by an adhesive, soldering, sintering, eutectic bonding, ultrasonically welding, and/or the like.

In further aspects, the second device component 300 may implement at least one active device 402. In aspects, the at least one active device 402 implemented by the second device component 300 may be arranged on the surface 302. In this aspect, the second device component 300 may be implemented as a flip chip.

Additionally or alternatively, the at least one active device 402 implemented by the second device component 300 may be arranged on a surface 304. In this aspect, the second device component 300 may be implemented as a non-flip chip.

In further aspects, the first device component 200 may implement the at least one active device 402. In aspects, the at least one active device 402 implemented by the first device component 200 may be arranged on the surface 202.

In aspects, the filled interconnect 108 may be metallic filled holes that may function as thermal tunnels through the interposer substrate 102. The filled interconnect 108 may comprise a metallic material such as copper, gold, nickel, palladium, silver, tin, a gold tin alloy, and the like, and combinations thereof. The filled interconnect 108 may have an axis that may be located in a plane generally perpendicular to the x-axis, a plane generally parallel to the y-axis, and/or a plane generally perpendicular to the first substrate surface 104 and/or the second substrate surface 106.

In aspects, the interposer substrate 102 may include vias extending through the interposer substrate 102 between and/or connecting the component configuration 124 and the component configuration 126 (not shown). The vias may be metallic plated holes or metallic filled holes that may function as electrical tunnels through the interposer substrate 102. The vias may comprise a metallic material such as copper, gold, nickel, palladium, silver, tin, a gold tin alloy, and the like, and combinations thereof. The vias may have an axis that may be located in a plane generally perpendicular to the x-axis, a plane generally parallel to the y-axis, and/or a plane generally perpendicular to the first substrate surface 104 and/or the second substrate surface 106.

In aspects, the at least one active device 402 may be implemented as one or more of a wide band-gap semiconductor device, an ultra-wideband device, a GaN based device, a LDMOS (Laterally-Diffused Metal-Oxide Semiconductor) device, a Metal Semiconductor Field-Effect Transistor (MESFET), a Metal Oxide Field Effect Transistor (MOSFET), a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, a power module, a gate driver, a component such as a General-Purpose Broadband component, a Telecom component, a L-Band component, a S-Band component, a X-Band component, a C-Band component, a Ku-Band component, a Satellite Communications component, a Doherty configuration, and/or the like.

In aspects, the microelectronic device 400 may be implemented as any type of device that may include one or more transistors, capacitors, inductors, resistors, diodes, insulators, conductors, and/or the like; may include leads, terminals, pads, and/or the like; may include digital integrated circuits (ICs), analog circuits, and/or the like.

In aspects, the first device component 200 and/or the second device component 300 may be implemented as a printed circuit board (PCB), a printed wiring board (PWB), a printed circuit board assembly (PCBA), a medium used to connect electronic components to one another in a controlled manner, and/or the like. In aspects, the first device component 200 and/or the second device component 300 may be implemented as a laminated sandwich structure of one or more conductive and insulating layers. In aspects, the first device component 200 and/or the second device component 300 may include one or more conductive layers, traces, planes and/or the like. In aspects, the first device component 200 and/or the second device component 300 may be etched from one or more sheet layers of copper laminated onto and/or between sheet layers of a non-conductive substrate. In aspects, the first device component 200 and/or the second device component 300 may be configured such that the at least one SMD and/or other electrical components may be fixed to the top or bottom thereof.

In aspects, the first device component 200 and/or the second device component 300 may include and/or may be a cooling device, a topside cooling device, a heat sink, a topside heat sink, a support, a surface, a package support, a package surface, a package support surface, a flange, a metal flange, a leadframe, a metal leadframe and/or the like.

In aspects, the microelectronic device 400 may be a package that may be implemented as a power package, a power amplifier package, a RF (radio frequency) package, a RF amplifier package, a RF power amplifier package, a RF power transistor package, a RF power amplifier transistor package, and/or the like.

In aspects, the first device component 200 and/or the second device component 300 may be implemented as at least part of a RF device. The first device component 200 and/or the second device component 300 may implement matching networks, harmonic termination circuitry, integrated passive devices (IPD), capacitors, resistors, inductors, and/or the like. In aspects, the first device component 200 and/or the second device component 300 may be used for matching networks, pre-matching, bias-decoupling, thermal-grounding, and/or the like in RF power products and/or the like.

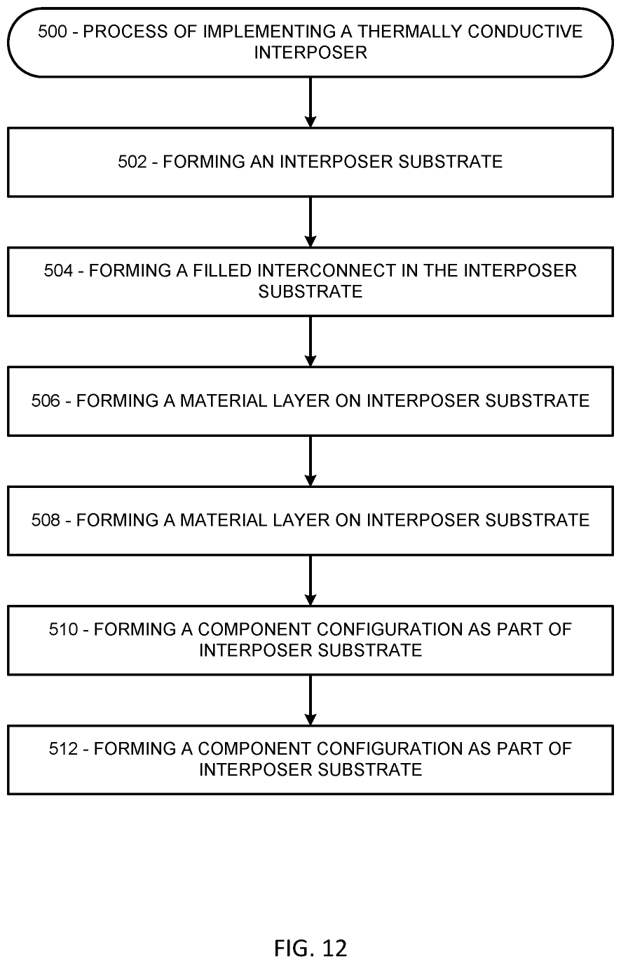

FIG. 12 illustrates a process of implementing the thermally conductive interposer according to aspects of the disclosure.

In particular, FIG. 12 illustrates a process of implementing a thermally conductive interposer 500. The process of implementing a thermally conductive interposer 500 may include forming an interposer substrate 502, forming a filled interconnect in the interposer substrate 504, and/or the like. In aspects, the process of implementing a thermally conductive interposer 500 may include forming a material layer on the interposer substrate 506, forming a material layer on the interposer substrate 508, and/or the like. In aspects, the process of implementing a thermally conductive interposer 500 may include forming a component configuration as part of interposer substrate, forming a component configuration as part of interposer substrate 510, and/or the like.

The process of implementing a thermally conductive interposer 500 may include a process of implementing the thermally conductive interposer 100 as described herein. Further, the forming an interposer substrate 502 may include forming the interposer substrate 102 as described herein.

In some aspects, the thermally conductive interposer 100 and/or the interposer substrate 102 may be formed cutting a substrate material wafer utilizing cutting equipment such as wafer, circuit board, or package sawing equipment to singulate the thermally conductive interposer 100 and/or the interposer substrate 102 from the wafer, which may have the advantage that the thermally conductive interposer 100 and/or the interposer substrate 102 may be arranged on dicing tape on a ring frame, which can be directly loaded to the Die Attach equipment for subsequent assembly into the second device component 300. The size of the thermally conductive interposer 100 and/or the interposer substrate 102 may be optimized to what subsequent assembly equipment like SMT, Dicing and Die Attach Equipment can handle.

Additionally, the forming a filled interconnect in the interposer substrate 504 may include forming the filled interconnect 108 in the interposer substrate 102 as described herein.

In aspects, the forming a material layer on the interposer substrate 506 may include forming the material layer 114 on interposer substrate 102 as described herein. Additionally, the forming a material layer on the interposer substrate 508 may include forming the material layer 116 on interposer substrate 102 as described herein.

In aspects, the forming a material layer on the interposer substrate 506 and/or the forming a material layer on the interposer substrate 508 may include may include utilizing one or more manufacturing techniques including print screening, silk screen printing processes, photoengraving processes, print onto transparent film processes, photo mask processes in combination with etching processes, photo-sensitized board processes, laser resist ablation processes, milling processes, laser etching processes, direct metal printing processes, sputtering processes, electroplating processes, photolithography processes, and/or like processes.

In aspects, the forming a component configuration as part of interposer substrate 510 may include forming the component configuration 124 as part of interposer substrate 102 as described herein. Further, the forming a component configuration as part of interposer substrate 512 may include forming the component configuration 126 as part of interposer substrate 102 as described herein.

In aspects, the forming a component configuration as part of interposer substrate 510 and/or the forming a component configuration as part of interposer substrate 512 may include utilizing one or more manufacturing techniques including print screening, silk screen printing processes, photoengraving processes, print onto transparent film processes, photo mask processes in combination with etching processes, photo-sensitized board processes, laser resist ablation processes, milling processes, laser etching processes, direct metal printing processes, sputtering processes, electroplating processes, photolithography processes, and/or like processes.

Accordingly, the disclosure has set forth an interposer configured with improved thermal conductivity. Moreover, the disclosure has set forth an interposer configured with improved mechanical integrity.

The following are a number of nonlimiting EXAMPLES of aspects of the disclosure.

One EXAMPLE: a thermally conductive interposer includes an interposer substrate having a first substrate surface and a second substrate surface. The thermally conductive interposer in addition includes the first substrate surface being configured to be attached to a first device component. The interposer moreover includes the second substrate surface being configured to be attached to a second device component. The interposer also includes the interposer substrate being configured to support the second device component on the first device component and integrate the first device component and the second device component within a microelectronic device. The interposer further includes where the interposer substrate includes a material having a Youngs Modulus greater than 200 GPa (Giga Pascals). The interposer in addition includes where the interposer substrate is configured to transfer heat between the first device component and the second device component. The interposer moreover includes where the interposer substrate is configured to be electrically nonconductive.

The above-noted EXAMPLE may further include any one or a combination of more than one of the following EXAMPLES:

The thermally conductive interposer of the above-noted EXAMPLE includes at least one redistribution line arranged on the first substrate surface and/or the second substrate surface. The thermally conductive interposer of the above-noted EXAMPLE where the at least one redistribution line includes at least one metal trace, at least one metal bond pad, at least one passive component, at least one metallic pillar, at least one solder bump, and/or at least one polyimide dielectric portion. The thermally conductive interposer of the above-noted EXAMPLE where the at least one redistribution line includes at least one passive component includes at least one capacitor, at least one inductor, and/or at least one resistor. The thermally conductive interposer of the above-noted EXAMPLE where the at least one redistribution line is configured to connect to a surface mount device (SMD). The thermally conductive interposer of the above-noted EXAMPLE where the at least one redistribution line includes at least one first redistribution line arranged on the first substrate surface and at least one second redistribution line arranged on the second substrate surface. The thermally conductive interposer of the above-noted EXAMPLE where the first device component includes at least one bond pad configured to electrically connect to the at least one first redistribution line; and where the second device component includes at least one bond pad configured to electrically connect to the at least one second redistribution line. The thermally conductive interposer of the above-noted EXAMPLE where the first device component is implemented as a flip configuration includes at least one transistor. The thermally conductive interposer of the above-noted EXAMPLE where the first device component includes at least one bond pad configured to electrically connect to the at least one redistribution line. The thermally conductive interposer of the above-noted EXAMPLE where the second device component includes at least one bond pad configured to electrically connect to the at least one redistribution line. The thermally conductive interposer of the above-noted EXAMPLE where the first device component includes at least one transistor. The thermally conductive interposer of the above-noted EXAMPLE where the interposer substrate includes a material having a band gap greater than 2 eV (electron volt). The thermally conductive interposer of the above-noted EXAMPLE where the interposer substrate includes a material having a breakdown strength greater than 1 MV/cm (Mega volts per centimeter). The thermally conductive interposer of the above-noted EXAMPLE where the interposer substrate includes a material having a melting point greater than 1500 degrees C. (Celsius). The thermally conductive interposer of the above-noted EXAMPLE where the interposer substrate includes a material having a dielectric constant less than 11. The thermally conductive interposer of the above-noted EXAMPLE where the interposer substrate includes a material having a Youngs Modulus greater than 300 GPa (Giga Pascals). The thermally conductive interposer of the above-noted EXAMPLE where the interposer substrate includes a material having a Youngs Modulus between 300 GPa (Giga Pascals) and 600 GPa. The thermally conductive interposer of the above-noted EXAMPLE where the interposer substrate includes a material having a thermal conductivity greater than 2 W/cm-K (watts per centimeter Kelvin). The thermally conductive interposer of the above-noted EXAMPLE where the interposer substrate includes a SiC (silicon carbide) substrate. The thermally conductive interposer of the above-noted EXAMPLE where the interposer substrate includes a diamond substrate. The thermally conductive interposer of the above-noted EXAMPLE where the interposer substrate includes a GaN (Gallium nitride) substrate. The thermally conductive interposer of the above-noted EXAMPLE where the interposer substrate includes an AlN (Aluminum nitride) substrate. The thermally conductive interposer of the above-noted EXAMPLE includes a layer arranged on the second substrate surface. The thermally conductive interposer of the above-noted EXAMPLE includes a GaN (Gallium nitride) layer arranged on the second substrate surface. The thermally conductive interposer of the above-noted EXAMPLE includes a SiC (silicon carbide) layer arranged on the second substrate surface. The thermally conductive interposer of the above-noted EXAMPLE includes a diamond layer arranged on the second substrate surface. The thermally conductive interposer of the above-noted EXAMPLE includes at least one via extending between the first substrate surface and the second substrate surface, where the at least one via is configured to transfer heat between the first device component and the second device component. The thermally conductive interposer of the above-noted EXAMPLE where the interposer substrate includes a SiC (silicon carbide) substrate having a resistivity less than 100,000 ohm-cm (ohm centimeter). The thermally conductive interposer of the above-noted EXAMPLE where the interposer substrate includes a SiC (silicon carbide) substrate having a resistivity less than 2,000 ohm-cm (ohm centimeter). The thermally conductive interposer of the above-noted EXAMPLE where the interposer substrate includes a SiC (silicon carbide) substrate having a resistivity between 800 ohm-cm (ohm centimeter) and 1,200 ohm-cm. The microelectronic device of the above-noted EXAMPLE and includes the first device component and the second device component.

One EXAMPLE: a process includes configuring an interposer substrate to includes a first substrate surface and a second substrate surface. The process in addition includes configuring the first substrate surface to be attached to a first device component. The process moreover includes configuring the second substrate surface to be attached to a second device component. The process also includes configuring the interposer substrate to support the second device component on the first device component and integrate the first device component and the second device component within a microelectronic device. The process further includes where the interposer substrate includes a material having a Youngs Modulus greater than 200 GPa (Giga Pascals). The process in addition includes where the interposer substrate is configured to transfer heat between the first device component and the second device component. The process moreover includes where the interposer substrate is configured to be electrically nonconductive.

The above-noted EXAMPLE may further include any one or a combination of more than one of the following EXAMPLES:

The process of the above-noted EXAMPLE includes arranging at least one redistribution line on the first substrate surface and/or the second substrate surface. The process of the above-noted EXAMPLE where the at least one redistribution line includes at least one metal trace, at least one metal bond pad, at least one passive component, at least one metallic pillar, at least one solder bump, and/or at least one polyimide dielectric portion. The process of the above-noted EXAMPLE where the at least one redistribution line includes at least one passive component includes at least one capacitor, at least one inductor, and/or at least one resistor. The process of the above-noted EXAMPLE where the at least one redistribution line is configured to connect to a surface mount device (SMD). The process of the above-noted EXAMPLE where the at least one redistribution line includes at least one first redistribution line arranged on the first substrate surface and at least one second redistribution line arranged on the second substrate surface. The process of the above-noted EXAMPLE where the first device component includes at least one bond pad configured to electrically connect to the at least one first redistribution line; and where the second device component includes at least one bond pad configured to electrically connect to the at least one second redistribution line. The process of the above-noted EXAMPLE where the first device component is implemented as a flip configuration includes at least one transistor. The process of the above-noted EXAMPLE where the first device component includes at least one bond pad configured to electrically connect to the at least one redistribution line. The process of the above-noted EXAMPLE where the second device component includes at least one bond pad configured to electrically connect to the at least one redistribution line. The process of the above-noted EXAMPLE where the first device component includes at least one transistor. The process of the above-noted EXAMPLE where the interposer substrate includes a material having a band gap greater than 2 eV (electron volt). The process of the above-noted EXAMPLE where the interposer substrate includes a material having a breakdown strength greater than 1 MV/cm (Mega volts per centimeter). The process of the above-noted EXAMPLE where the interposer substrate includes a material having a melting point greater than 1500 degrees C. (Celsius). The process of the above-noted EXAMPLE where the interposer substrate includes a material having a dielectric constant less than 11. The process of the above-noted EXAMPLE where the interposer substrate includes a material having a Youngs Modulus greater than 300 GPa (Giga Pascals). The process of the above-noted EXAMPLE where the interposer substrate includes a material having a Youngs Modulus between 300 GPa (Giga Pascals) and 600 GPa. The process of the above-noted EXAMPLE where the interposer substrate includes a material having a thermal conductivity greater than 2 W/cm-K (watts per centimeter Kelvin). The process of the above-noted EXAMPLE where the interposer substrate includes a SiC (silicon carbide) substrate. The process of the above-noted EXAMPLE where the interposer substrate includes a diamond substrate. The process of the above-noted EXAMPLE where the interposer substrate includes a GaN (Gallium nitride) substrate. The process of the above-noted EXAMPLE where the interposer substrate includes an AlN (Aluminum nitride) substrate. The process of the above-noted EXAMPLE includes a layer arranged on the second substrate surface. The process of the above-noted EXAMPLE includes a GaN (Gallium nitride) layer arranged on the second substrate surface. The process of the above-noted EXAMPLE includes a SiC (silicon carbide) layer arranged on the second substrate surface. The process of the above-noted EXAMPLE includes a diamond layer arranged on the second substrate surface. The process of the above-noted EXAMPLE includes at least one via extending between the first substrate surface and the second substrate surface, where the at least one via is configured to transfer heat between the first device component and the second device component. The process of the above-noted EXAMPLE where the interposer substrate includes a SiC (silicon carbide) substrate having a resistivity less than 100,000 ohm-cm (ohm centimeter). The process of the above-noted EXAMPLE where the interposer substrate includes a SiC (silicon carbide) substrate having a resistivity less than 2,000 ohm-cm (ohm centimeter). The process of the above-noted EXAMPLE where the interposer substrate includes a SiC (silicon carbide) substrate having a resistivity between 800 ohm-cm (ohm centimeter) and 1,200 ohm-cm. The process of the above-noted EXAMPLE includes implementing a thermally conductive interposer in a microelectronic device includes the first device component and the second device component.

One EXAMPLE: a thermally conductive interposer includes an interposer substrate having a first substrate surface and a second substrate surface. The thermally conductive interposer in addition includes the first substrate surface being configured to be attached to a first device component. The interposer moreover includes the second substrate surface being configured to be attached to a second device component. The interposer also includes the interposer substrate being configured to support the second device component on the first device component and integrate the first device component and the second device component within a microelectronic device. The interposer further includes where the interposer substrate includes a material having a thermal conductivity greater than 2 W/cm-K (watts per centimeter Kelvin). The interposer in addition includes where the interposer substrate is configured to transfer heat between the first device component and the second device component. The interposer moreover includes where the interposer substrate is configured to be electrically nonconductive.

The above-noted EXAMPLE may further include any one or a combination of more than one of the following EXAMPLES:

The thermally conductive interposer of the above-noted EXAMPLE includes at least one redistribution line arranged on the first substrate surface and/or the second substrate surface. The thermally conductive interposer of the above-noted EXAMPLE where the at least one redistribution line includes at least one metal trace, at least one metal bond pad, at least one passive component, at least one metallic pillar, at least one solder bump, and/or at least one polyimide dielectric portion. The thermally conductive interposer of the above-noted EXAMPLE where the at least one redistribution line includes at least one passive component includes at least one capacitor, at least one inductor, and/or at least one resistor. The thermally conductive interposer of the above-noted EXAMPLE where the at least one redistribution line is configured to connect to a surface mount device (SMD). The thermally conductive interposer of the above-noted EXAMPLE where the at least one redistribution line includes at least one first redistribution line arranged on the first substrate surface and at least one second redistribution line arranged on the second substrate surface. The thermally conductive interposer of the above-noted EXAMPLE where the first device component includes at least one bond pad configured to electrically connect to the at least one first redistribution line; and where the second device component includes at least one bond pad configured to electrically connect to the at least one second redistribution line. The thermally conductive interposer of the above-noted EXAMPLE where the first device component is implemented as a flip configuration includes at least one transistor. The thermally conductive interposer of the above-noted EXAMPLE where the first device component includes at least one bond pad configured to electrically connect to the at least one redistribution line. The thermally conductive interposer of the above-noted EXAMPLE where the second device component includes at least one bond pad configured to electrically connect to the at least one redistribution line. The thermally conductive interposer of the above-noted EXAMPLE where the first device component includes at least one transistor. The thermally conductive interposer of the above-noted EXAMPLE where the interposer substrate includes a material having a band gap greater than 2 eV (electron volt). The thermally conductive interposer of the above-noted EXAMPLE where the interposer substrate includes a material having a breakdown strength greater than 1 MV/cm (Mega volts per centimeter). The thermally conductive interposer of the above-noted EXAMPLE where the interposer substrate includes a material having a melting point greater than 1500 degrees C. (Celsius). The thermally conductive interposer of the above-noted EXAMPLE where the interposer substrate includes a material having a dielectric constant less than 11. The thermally conductive interposer of the above-noted EXAMPLE where the interposer substrate includes a material having a Youngs Modulus greater than 200 GPa (Giga Pascals). The thermally conductive interposer of the above-noted EXAMPLE where the interposer substrate includes a material having a Youngs Modulus between 300 GPa (Giga Pascals) and 600 GPa. The thermally conductive interposer of the above-noted EXAMPLE where the interposer substrate includes a SiC (silicon carbide) substrate. The thermally conductive interposer of the above-noted EXAMPLE where the interposer substrate includes a diamond substrate. The thermally conductive interposer of the above-noted EXAMPLE where the interposer substrate includes a GaN (Gallium nitride) substrate. The thermally conductive interposer of the above-noted EXAMPLE where the interposer substrate includes an AlN (Aluminum nitride) substrate. The thermally conductive interposer of the above-noted EXAMPLE includes a layer arranged on the second substrate surface. The thermally conductive interposer of the above-noted EXAMPLE includes a GaN (Gallium nitride) layer arranged on the second substrate surface. The thermally conductive interposer of the above-noted EXAMPLE includes a SiC (silicon carbide) layer arranged on the second substrate surface. The thermally conductive interposer of the above-noted EXAMPLE includes a diamond layer arranged on the second substrate surface. The thermally conductive interposer of the above-noted EXAMPLE includes at least one via extending between the first substrate surface and the second substrate surface, where the at least one via is configured to transfer heat between the first device component and the second device component. The thermally conductive interposer of the above-noted EXAMPLE where the interposer substrate includes a SiC (silicon carbide) substrate having a resistivity less than 100,000 ohm-cm (ohm centimeter). The thermally conductive interposer of the above-noted EXAMPLE where the interposer substrate includes a SiC (silicon carbide) substrate having a resistivity less than 2,000 ohm-cm (ohm centimeter). The thermally conductive interposer of the above-noted EXAMPLE where the interposer substrate includes a SiC (silicon carbide) substrate having a resistivity between 800 ohm-cm (ohm centimeter) and 1,200 ohm-cm. The microelectronic device of the above-noted EXAMPLE and includes the first device component and the second device component.

One EXAMPLE: a process includes configuring an interposer substrate to includes a first substrate surface and a second substrate surface. The process in addition includes configuring the first substrate surface to be attached to a first device component. The process moreover includes configuring the second substrate surface to be attached to a second device component. The process also includes configuring the interposer substrate to support the second device component on the first device component and integrate the first device component and the second device component within a microelectronic device. The process further includes where the interposer substrate includes a material having a thermal conductivity greater than 2 W/cm-K (watts per centimeter Kelvin). The process in addition includes where the interposer substrate is configured to transfer heat between the first device component and the second device component. The process moreover includes where the interposer substrate is configured to be electrically nonconductive.

The above-noted EXAMPLE may further include any one or a combination of more than one of the following EXAMPLES:

The process of the above-noted EXAMPLE includes arranging at least one redistribution line on the first substrate surface and/or the second substrate surface. The process of the above-noted EXAMPLE where the at least one redistribution line includes at least one metal trace, at least one metal bond pad, at least one passive component, at least one metallic pillar, at least one solder bump, and/or at least one polyimide dielectric portion. The process of the above-noted EXAMPLE where the at least one redistribution line includes at least one passive component includes at least one capacitor, at least one inductor, and/or at least one resistor. The process of the above-noted EXAMPLE where the at least one redistribution line is configured to connect to a surface mount device (SMD). The process of the above-noted EXAMPLE where the at least one redistribution line includes at least one first redistribution line arranged on the first substrate surface and at least one second redistribution line arranged on the second substrate surface. The process of the above-noted EXAMPLE where the first device component includes at least one bond pad configured to electrically connect to the at least one first redistribution line; and where the second device component includes at least one bond pad configured to electrically connect to the at least one second redistribution line. The process of the above-noted EXAMPLE where the first device component is implemented as a flip configuration includes at least one transistor. The process of the above-noted EXAMPLE where the first device component includes at least one bond pad configured to electrically connect to the at least one redistribution line. The process of the above-noted EXAMPLE where the second device component includes at least one bond pad configured to electrically connect to the at least one redistribution line. The process of the above-noted EXAMPLE where the first device component includes at least one transistor. The process of the above-noted EXAMPLE where the interposer substrate includes a material having a band gap greater than 2 eV (electron volt). The process of the above-noted EXAMPLE where the interposer substrate includes a material having a breakdown strength greater than 1 MV/cm (Mega volts per centimeter). The process of the above-noted EXAMPLE where the interposer substrate includes a material having a melting point greater than 1500 degrees C. (Celsius). The process of the above-noted EXAMPLE where the interposer substrate includes a material having a dielectric constant less than 11. The process of the above-noted EXAMPLE where the interposer substrate includes a material having a Youngs Modulus greater than 200 GPa (Giga Pascals). The process of the above-noted EXAMPLE where the interposer substrate includes a material having a Youngs Modulus between 300 GPa (Giga Pascals) and 600 GPa. The process of the above-noted EXAMPLE where the interposer substrate includes a SiC (silicon carbide) substrate. The process of the above-noted EXAMPLE where the interposer substrate includes a diamond substrate. The process of the above-noted EXAMPLE where the interposer substrate includes a GaN (Gallium nitride) substrate. The process of the above-noted EXAMPLE where the interposer substrate includes an AlN (Aluminum nitride) substrate. The process of the above-noted EXAMPLE includes a layer arranged on the second substrate surface. The process of the above-noted EXAMPLE includes a GaN (Gallium nitride) layer arranged on the second substrate surface. The process of the above-noted EXAMPLE includes a SiC (silicon carbide) layer arranged on the second substrate surface. The process of the above-noted EXAMPLE includes a diamond layer arranged on the second substrate surface. The process of the above-noted EXAMPLE includes at least one via extending between the first substrate surface and the second substrate surface, where the at least one via is configured to transfer heat between the first device component and the second device component. The process of the above-noted EXAMPLE where the interposer substrate includes a SiC (silicon carbide) substrate having a resistivity less than 100,000 ohm-cm (ohm centimeter). The process of the above-noted EXAMPLE where the interposer substrate includes a SiC (silicon carbide) substrate having a resistivity less than 2,000 ohm-cm (ohm centimeter). The process of the above-noted EXAMPLE where the interposer substrate includes a SiC (silicon carbide) substrate having a resistivity between 800 ohm-cm (ohm centimeter) and 1,200 ohm-cm. The process of the above-noted EXAMPLE includes implementing a thermally conductive interposer in a microelectronic device includes the first device component and the second device component.

The adhesive of the disclosure may be utilized in an adhesive bonding process that may include applying an intermediate layer to connect surfaces to be connected. The adhesive may be organic or inorganic; and the adhesive may be deposited on one or both surfaces of the surface to be connected. The adhesive may be utilized in an adhesive bonding process that may include applying adhesive material with a particular coating thickness, at a particular bonding temperature, for a particular processing time while in an environment that may include applying a particular tool pressure. In one aspect, the adhesive may be a conductive adhesive, an epoxy-based adhesive, a conductive epoxy-based adhesive, and/or the like.

The solder of the disclosure may be utilized to form a solder interface that may include solder and/or be formed from solder. The solder may be any fusible metal alloy that may be used to form a bond between surfaces to be connected. The solder may be a lead-free solder, a lead solder, a eutectic solder, or the like. The lead-free solder may contain tin, copper, silver, bismuth, indium, zinc, antimony, traces of other metals, and/or the like. The lead solder may contain lead, other metals such as tin, silver, and/or the like. The solder may further include flux as needed.

The sintering of the disclosure may utilize a process of compacting and forming a conductive mass of material by heat and/or pressure. The sintering process may operate without melting the material to the point of liquefaction. The sintering process may include sintering of metallic nano or hybrid powders in pastes or epoxies. The sintering process may include sintering in a vacuum. The sintering process may include sintering with the use of a protective gas.

The eutectic bonding of the disclosure may utilize a eutectic soldering process that may form a eutectic system. The eutectic system may be used between surfaces to be connected. The eutectic bonding may utilize metals that may be alloys and/or intermetallics that transition from solid to liquid state, or from liquid to solid state, at a specific composition and temperature. The eutectic alloys may be deposited by sputtering, evaporation, electroplating, and/or the like.

The ultrasonically welding of the disclosure may utilize a process whereby high-frequency ultrasonic acoustic vibrations are locally applied to components being held together under pressure. The ultrasonically welding may create a solid-state weld between surfaces to be connected. In one aspect, the ultrasonically welding may include applying a sonicated force.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure.

1. A thermally conductive interposer comprising:
an interposer substrate having a first substrate surface and a second substrate surface;
the first substrate surface being configured to be attached to a first device component;
the second substrate surface being configured to be attached to a second device component; and
the interposer substrate being configured to support the second device component on the first device component and integrate the first device component and the second device component within a microelectronic device,
wherein the interposer substrate comprises a material having a thermal conductivity greater than 1.5 W/cm-K (watts per centimeter Kelvin);
wherein the interposer substrate comprises a material having a Youngs Modulus greater than 200 GPa (Giga Pascals);
wherein the interposer substrate is configured to transfer heat between the first device component and the second device component; and
wherein the interposer substrate is configured to be electrically nonconductive.

2. The thermally conductive interposer according to claim 1 further comprising at least one redistribution line arranged on the first substrate surface and/or the second substrate surface.

3. The thermally conductive interposer according to claim 2 wherein the at least one redistribution line comprises at least one metal trace, at least one metal bond pad, at least one passive component, at least one metallic pillar, at least one solder bump, and/or at least one polyimide dielectric portion.

4. The thermally conductive interposer according to claim 2 wherein the at least one redistribution line comprises at least one passive component comprising at least one capacitor, at least one inductor, and/or at least one resistor.

5. The thermally conductive interposer according to claim 2 wherein the at least one redistribution line is configured to connect to a surface mount device (SMD).

6. The thermally conductive interposer according to claim 2 wherein the at least one redistribution line comprises at least one first redistribution line arranged on the first substrate surface and at least one second redistribution line arranged on the second substrate surface.

7. The thermally conductive interposer according to claim 1 wherein the first device component comprises at least one transistor.

8. The thermally conductive interposer according to claim 2 wherein the first device component comprises at least one bond pad configured to electrically connect to the at least one redistribution line.

9. The thermally conductive interposer according to claim 2 wherein the second device component comprises at least one bond pad configured to electrically connect to the at least one redistribution line.

10. The thermally conductive interposer according to claim 6
wherein the first device component comprises at least one bond pad configured to electrically connect to the at least one first redistribution line; and
wherein the second device component comprises at least one bond pad configured to electrically connect to the at least one second redistribution line.

11. The thermally conductive interposer according to claim 6 wherein the first device component is implemented as a flip configuration comprising at least one transistor.

12. The thermally conductive interposer according to claim 1 wherein the interposer substrate comprises a material having a band gap greater than 2 eV (electron volt).

13. The thermally conductive interposer according to claim 1 wherein the interposer substrate comprises a material having a breakdown strength greater than 1 MV/cm (Mega volts per centimeter).

14. The thermally conductive interposer according to claim 1 wherein the interposer substrate comprises a material having a melting point greater than 1500 degrees C. (Celsius).

15. The thermally conductive interposer according to claim 1 wherein the interposer substrate comprises a material having a dielectric constant less than 11.

16. The thermally conductive interposer according to claim 1 wherein the interposer substrate comprises a material having a Youngs Modulus greater than 300 GPa (Giga Pascals).

17. The thermally conductive interposer according to claim 1 wherein the interposer substrate comprises a material having a Youngs Modulus between 300 GPa (Giga Pascals) and 600 GPa.

18. The thermally conductive interposer according to claim 1 wherein the interposer substrate comprises a material having a thermal conductivity greater than 2 W/cm-K (watts per centimeter Kelvin).

19. The thermally conductive interposer according to claim 1 wherein the interposer substrate comprises a SiC (silicon carbide) substrate.

20.-62. (canceled)

63. A thermally conductive interposer comprising:
an interposer substrate having a first substrate surface and a second substrate surface;
the first substrate surface being configured to be attached to a first device component;
the second substrate surface being configured to be attached to a second device component; and
the interposer substrate being configured to support the second device component on the first device component and integrate the first device component and the second device component within a microelectronic device,
wherein the interposer substrate comprises a material having a thermal conductivity greater than 2 W/cm-K (watts per centimeter Kelvin);
wherein the interposer substrate is configured to transfer heat between the first device component and the second device component; and
wherein the interposer substrate is configured to be electrically nonconductive.

64.-79. (canceled)

80. The thermally conductive interposer according to claim 63 wherein the interposer substrate comprises a SiC (silicon carbide) substrate.

81.-92. (canceled)

93. A process of implementing a thermally conductive interposer, the process comprising:
configuring an interposer substrate to comprise a first substrate surface and a second substrate surface;
configuring the first substrate surface to be attached to a first device component;
configuring the second substrate surface to be attached to a second device component; and
configuring the interposer substrate to support the second device component on the first device component and integrate the first device component and the second device component within a microelectronic device,
wherein the interposer substrate comprises a material having a thermal conductivity greater than 2 W/cm-K (watts per centimeter Kelvin);
wherein the interposer substrate is configured to transfer heat between the first device component and the second device component; and
wherein the interposer substrate is configured to be electrically nonconductive.

94. The process of implementing a thermally conductive interposer according to claim 93 further comprising arranging at least one redistribution line on the first substrate surface and/or the second substrate surface.

95.-122. (canceled)
